(19) United States
(12) Patent Application Publication
(10) Pub. No.: US 2007/0252284 A1
(43) Pub. Date: Nov. 1, 2007

(54) Stackable semiconductor package

(76) Inventors: Po-Ching Su, Kaohsiung (TW); Cheng-Yin Lee, Kaohsiung (TW); Ying-Tsai Yeh, Kaohsiung (TW); Gwo-Liang Weng, Kaohsiung (TW)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/636,975

(22) Filed: Dec. 12, 2006

(30) Foreign Application Priority Data
Apr. 28, 2006 (TW) 095115345

(51) Int. Cl. H01L 23/52

(52) U.S. Cl. 257/777

(57) ABSTRACT

The present invention relates to a stackable semiconductor package. The stackable semiconductor package includes a first substrate, a chip, a first molding compound, a second substrate, a plurality of first wires, and a second molding compound. The chip is disposed on the first substrate. The second substrate is disposed on the first molding compound. The area of the first molding compound is adjusted according to the area of the second substrate, so as to support the second substrate. The first wires electrically connect the first substrate and the second substrate. Some pads of the second substrate are exposed outside the second molding compound. Therefore, the second substrate will not shake or sway during a wire bonding process, and the area of the second substrate can be increased to receive more devices disposed thereon.

### BACKGROUND OF THE INVENTION

1. Field of the Invention

The present invention relates to a stackable semiconductor package.

2. Description of the Related Art

FIG. 1 is a schematic sectional view of a conventional stackable semiconductor package. The conventional stackable semiconductor package 1 includes a first substrate 11, a chip 12, a spacer 13, a second substrate 14, a plurality of first wires 15, and a first molding compound 16.

The first substrate 11 has a first surface 111 and a second surface 112. The chip 12 has a first surface 121 and a second surface 122. The second surface 122 of the chip 12 is adhered to the first surface 111 of the first substrate 11 by the use of an adhesive layer 17. The first surface 121 of the chip 12 is electrically connected to the first surface 111 of the first substrate 11 via a plurality of second wires 18. The spacer 13 is adhered to the first surface 121 of the chip 12. The second substrate 14 has a first surface 141 and a second surface 142. The second surface 142 of the second substrate 14 is adhered to the spacer 13. The first surface 141 of the second substrate 14 has a plurality of first pads 143 and a plurality of second pads 144 disposed thereon. From a top view, the area of the second substrate 14 is larger than that of the chip 12. Therefore, the spacer 13 is needed to support the second substrate 14 to prevent the second substrate 14 from pressing the second wires 18.

The first wires 15 electrically connect the first pads 143 of the second substrate 14 to the first surface 111 of the first substrate 11. The first molding compound 16 encapsulates the first surface 111 of the first substrate 11, the chip 12, the second wires 18, the spacer 13, a portion of the second substrate 14, and the first wires 15, and the second pads 144 on the first surface 141 of the second substrate 14 are exposed outside the first molding compound 16, thereby forming a mold area opening 19. Under ordinary circumstances, the conventional stackable semiconductor package 1 includes another package 20 or other devices stacked at the mold area opening 19, wherein solder balls 201 of the package 20 are electrically connected to the second pads 144 of the second substrate 14.

The disadvantages of the conventional stackable semiconductor package 1 are described as follows. First, the spacer 13 is a plate, which is precut into the desired size and then is coated with a gel to be adhered to the chip 12. After that, the second substrate 14 is adhered to the spacer 13. The above steps are complicated, and have difficulty in alignment. Secondly, the spacer 13 cannot contact the second wires 18, so the area thereof must be smaller than that of the chip 12. However, as the area of the second substrate 14 is larger than that of the chip 12, the second substrate 14 partially extends beyond the spacer 13, thus forming an overhang portion. Under common circumstances, the first pads 143 are disposed at the overhang portion (i.e., the periphery of the corresponding position of the spacer 13 or the chip 12), and the distance between the corresponding position of the first pads 143 and the edge of the spacer 13 is defined as an overhang length L1. Experimental results show that during the wire bonding process, when the overhang length L1 is more than three times larger than the thickness T1 of the second substrate 14, the overhang portion may shake or sway, which is disadvantageous for the wire bonding process. Further, during the wire bonding process, when the second substrate 14 is subjected to an excessive downward stress, the second substrate 14 may be cracked. Then, due to the above sway, shake or crack, the overhang portion cannot be too long, which would limit the area of the second substrate 14, thus further limiting the layout space of the second pads 144 on the first surface 141 of the second substrate 14 exposed at the mold area opening 19. Finally, in order to overcome the above sway, shake or crack, the second substrate 14 cannot be too thin, such that the overall thickness of the conventional stackable semiconductor package 1 cannot be effectively reduced.

Therefore, it is necessary to provide a stackable semiconductor package to solve the above problems.

### SUMMARY OF THE INVENTION

The objective of the present invention is to provide a stackable semiconductor package, which comprises a first substrate, a chip, a first molding compound, a second substrate, a plurality of first wires, and a second molding compound. The first substrate has a first surface and a second surface. The chip is disposed on the first surface of the first substrate, and is electrically connected thereto. The first molding compound encapsulates the chip and a portion of the first surface of the first substrate. The second substrate is disposed on the first molding compound and has a first surface and a second surface. The first surface of the second substrate has a plurality of first pads and a plurality of second pads disposed thereon. The area of the first molding compound is adjusted according to the area of the second substrate, so as to support the second substrate. The first wires electrically connect the first pads of the second substrate to the first surface of the first substrate. The second molding compound encapsulates the first surface of the first substrate, the first molding compound, the first wires, and a portion of the second substrate, and the second pads on the first surface of the second substrate are exposed outside the second molding compound. Therefore, the overhang portion of the second substrate will not shake or sway during a wire bonding process, and the area of the second substrate can be increased to receive more devices disposed thereon. In addition, the thickness of the second substrate can be reduced, so as to reduce the overall thickness of the stackable semiconductor package.

### BRIEF DESCRIPTION OF THE DRAWINGS

FIG. 1 is a schematic sectional view of the conventional stackable semiconductor package;

FIG. 2 is a schematic sectional view of the stackable semiconductor package according to the first embodiment of the present invention;

FIG. 3 is a schematic sectional view of the stackable semiconductor package according to the second embodiment of the present invention;

FIG. 4 is a schematic sectional view of the stackable semiconductor package according to the third embodiment of the present invention; and

FIG. 5 is a schematic sectional view of the stackable semiconductor package according to the fourth embodiment of the present invention.

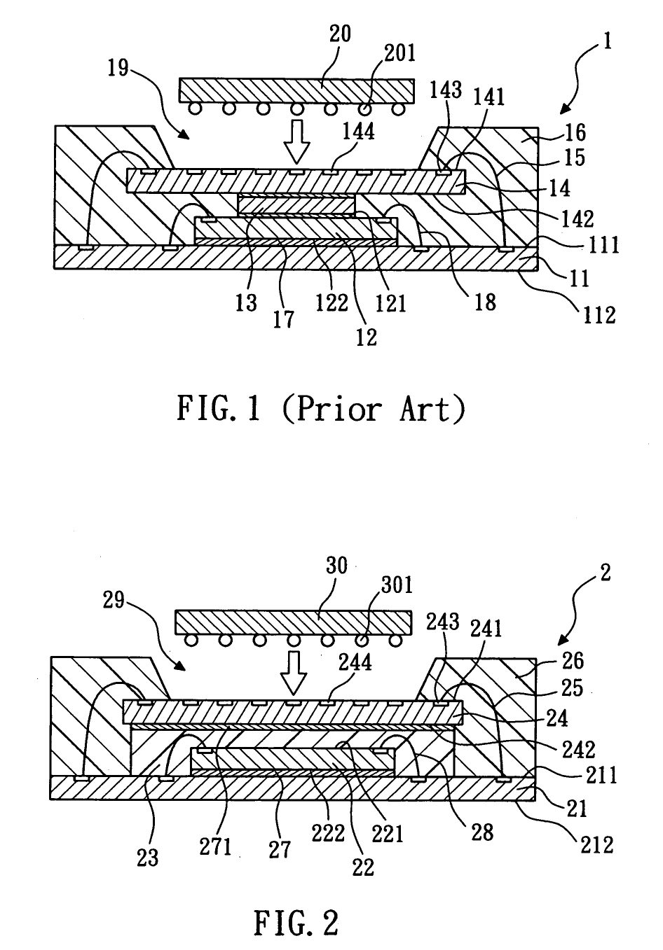

### DETAILED DESCRIPTION OF THE INVENTION

FIG. 2 is a schematic sectional view of the stackable semiconductor package according to the first embodiment of the present invention. The stackable semiconductor package 2 includes a first substrate 21, a chip 22, a first molding compound 23, a second substrate 24, a plurality of first wires 25, and a second molding compound 26. The first substrate 21 has a first surface 211 and a second surface 212. The chip 22 has a first surface 221 and a second surface 222. The second surface 222 of the chip 22 is adhered to the first surface 211 of the first substrate 21 by the use of an adhesive layer 27. The first surface 221 of the chip 22 is electrically connected to the first surface 211 of the first substrate 21 via a plurality of second wires 28. The first molding compound 23 encapsulates the chip 22, the second wires 28, and a portion of the first surface 211 of the first substrate 21.

The second substrate 24 has a first surface 241 and a second surface 242. The second surface 242 of the second substrate 24 is directly adhered to the first molding compound 23 by the use of an adhesive layer 271. The first surface 241 of the second substrate 24 has a plurality of first pads 243 and a plurality of second pads 244 disposed thereon, and the first pads 243 are disposed on the periphery of a corresponding position of the chip 22. The area of the first molding compound 23 is adjusted according to the area of the second substrate 24. That is, the area of the first molding compound 23 is extended to be close to the area of the second substrate 24, so as to support the second substrate 24 to prevent the second substrate 24 from swaying during the wire bonding process. Moreover, the area of the second substrate 24 can be increased to receive more devices disposed thereon. In addition, the thickness of the second substrate 24 can be reduced, so as to reduce the overall thickness of the stackable semiconductor package 2. In the present embodiment, the first substrate 21, the chip 22, and the first molding compound 23 constitute a wire-bonding package. However, it is reasonable that the chip 22 can be a flip chip attached to the first surface 211 of the first substrate 21.

The first wires 25 electrically connect the first pads 243 of the second substrate 24 to the first surface 211 of the first substrate 21. The second molding compound 26 encapsulates the first surface 211 of the first substrate 21, the first molding compound 23, a portion of the second substrate 24, and the first wires 25, and the second pads 244 on the first surface 241 of the second substrate 24 are exposed 1S outside the second molding compound 26, thus forming a mold area opening 29. Under common circumstances, the stackable semiconductor package 2 further includes another package 30 or other devices stacked at the mold area opening 29, wherein solder balls 301 of the package 30 are electrically connected to the second pads 244 of the second substrate 24.

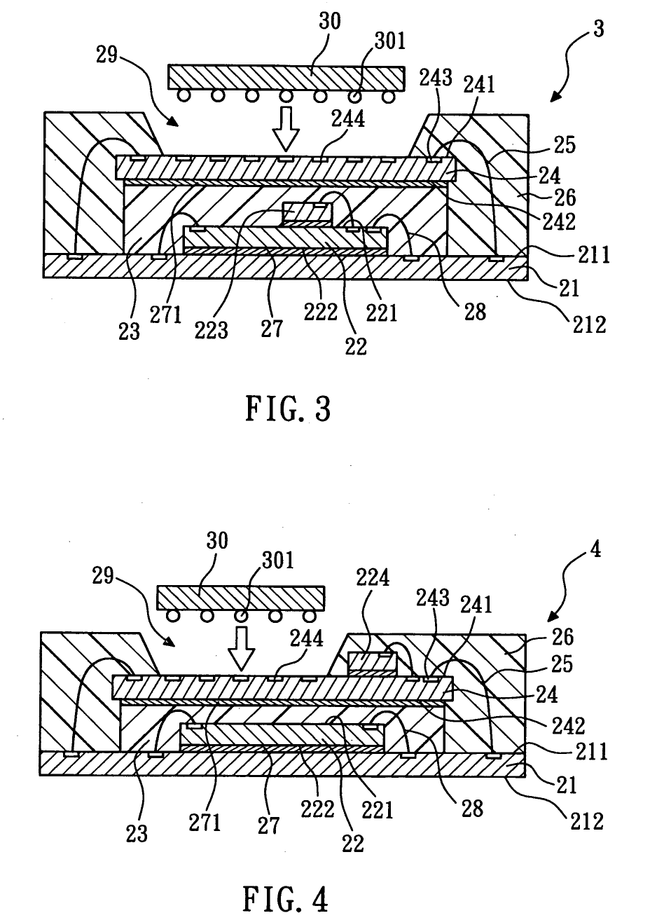

FIG. 3 is a schematic sectional view of the stackable semiconductor package according to the second embodiment of the present invention. The stackable semiconductor package 3 of the present embodiment is similar to the stackable semiconductor package 2 of the first embodiment, in which the identical devices are indicated by the same reference numerals. The difference therebetween lies in that a semiconductor device 223 is added in the present embodiment, which is disposed on the first surface 221 of the chip 22 and encapsulated by the first molding compound 23. In the present embodiment, the semiconductor device 223 is a chip electrically connected to the chip 22 by wire bonding or flip chip bonding. However, in another application, the semiconductor device 223 can be a package.

FIG. 4 is a schematic sectional view of the stackable semiconductor package according to the third embodiment of the present invention. The stackable semiconductor package 4 of the present embodiment is similar to the stackable semiconductor package 2 of the first embodiment, in which the identical devices are indicated by the same reference numerals. The difference therebetween lies in that a semiconductor device 224 is added in the present embodiment, which is disposed on the first surface 241 of the second substrate 24 and encapsulated by the second molding compound 26. In the present embodiment, the semiconductor device 224 is a chip electrically connected to the first surface 241 of the second substrate 24 by wire bonding or flip chip bonding. However, in another application, the semiconductor device 224 can be a package.

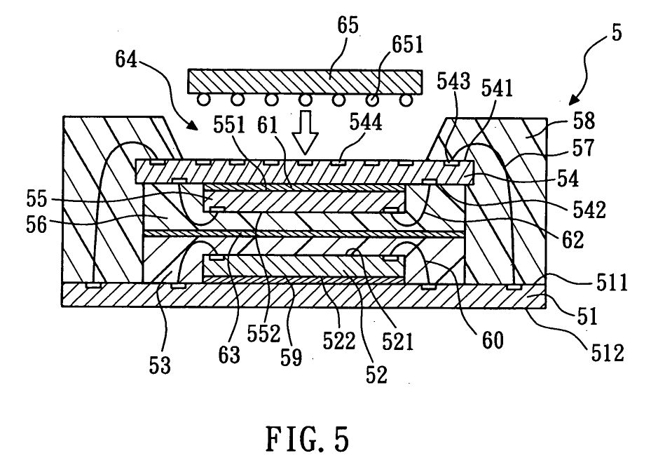

FIG. 5 is a schematic sectional view of the stackable semiconductor package according to the fourth embodiment of the present invention. The stackable semiconductor package 5 includes a first substrate 51, a first chip 52, a first molding compound 53, a second substrate 54, a second chip 55, a third molding compound 56, a plurality of first wires 57, and a second molding compound 58. The first substrate 51 has a first surface 511 and a second surface 512. The first chip 52 has a first surface 521 and a second surface 522. The second surface 522 of the first chip 52 is adhered to the first surface 511 of the first substrate 51 by the use of an adhesive layer 59. The first surface 521 of the first chip 52 is electrically connected to the first surface 511 of the first substrate 51 via a plurality of second wires 60. The first molding compound 53 encapsulates the first chip 52, the second wires 60, and a portion of the first surface 511 of the first substrate 51.

The second substrate 54 has a first surface 541 and a second surface 542. The second chip 55 has a first surface 551 and a second surface 552. The first surface 551 of the second chip 55 is adhered to the second surface 542 of the second substrate 54 by the use of an adhesive layer 61. The second surface 552 of the second chip 55 is electrically connected to the second surface 542 of the second substrate 54 via a plurality of third wires 62. The third molding compound 56 encapsulates the second chip 55, the third wires 62, and a portion of the second surface 542 of the second substrate 54, and is directly adhered to the first molding compound 53 by the use of an adhesive layer 63.

The first surface 541 of the second substrate 54 has a plurality of first pads 543 and a plurality of second pads 544 disposed thereon. The area of the first molding compound 53 is adjusted according to the area of the second substrate 54 and the third molding compound 56. That is, the area of the first molding compound 53 is extended to be close to the area of the second substrate 54 and third molding compound 56, so as to support the second substrate 54 to prevent the second substrate 54 from swaying during the wire bonding process. In the present embodiment, the first substrate 51, the first chip 52, and the first molding compound 53 constitute a wire-bonding package. However, it is reasonable that the first chip 52 can be a flip chip attached to the first surface 511 of the first substrate 51. Furthermore, in the present embodiment, the second substrate 54, the second chip 55, and the third molding compound 56 constitute a wire-bonding package. However, it is reasonable that the second chip 55 can be a flip chip attached to the second surface 541 of the second substrate 54.

The first wires 57 electrically connect the first pads 543 of the second substrate 54 to the first surface 511 of the first substrate 51. The second molding compound 58 encapsulates the first surface 511 of the first substrate 51, the first molding compound 53, a portion of the second substrate 54, the third molding compound 56, and the first wires 57, and the second pads 544 on the first surface 541 of the second substrate 54 are exposed outside the second molding compound 58, thus forming a mold area opening 64. Under ordinary circumstances, the stackable semiconductor package 5 further includes another package 65 or other devices stacked at the mold area opening 64, wherein solder balls 651 of the package 65 are electrically connected to the second pads 544 of the second substrate 54.

The method of fabricating the stackable semiconductor package of the present invention is illustrated with reference to the first embodiment below. Referring to FIG. 2, the method of fabricating the stackable semiconductor package of the present invention includes the following steps.

First, a package including a first substrate 21, a chip 22, and a first molding compound 23 is provided. The first substrate 21 has a first surface 211 and a second surface 212. The chip 22 is disposed on the first surface 211 of the first substrate 21. The chip 22 has a first surface 221 and a second surface 222. The second surface 222 of the chip 22 is adhered to the first surface 211 of the first substrate 21 by the use of an adhesive layer 27. The first surface 221 of the chip 22 is electrically connected to the first surface 211 of the first substrate 21 via a plurality of second wires 28. The first molding compound 23 encapsulates the chip 22, the second wires 28, and a portion of the first surface 211 of the first substrate 21.

In the present embodiment, the package is a wire-bonding package. However, it is reasonable that the chip 22 can be a flip chip attached to the first surface 211 of the first substrate 21. Preferably, the package further includes a semiconductor device 223 (FIG. 3) disposed on the chip 22. The semiconductor device 223 is electrically connected to the chip 22 and is encapsulated by the first molding compound 23.

Then, a second substrate 24 is provided, which is disposed above the first molding compound 23. The second substrate 24 has a first surface 241 and a second surface 242. The second surface 242 of the second substrate 24 is directly adhered to the first molding compound 23 by the use of an adhesive layer 271. The first surface 241 of the second substrate 24 has a plurality of first pads 243 and a plurality of second pads 244 disposed thereon. The area of the first molding compound 23 is adjusted according to the area of the second substrate 24.

Preferably, a step of disposing a semiconductor device 224 (FIG. 4) on the first surface 241 of the second substrate 24 is further included. The semiconductor device 224 is electrically connected to the first surface 241 of the second substrate 24.

Afterward, a plurality of first wires 25 is provided. The first wires 25 electrically connect the first pads 243 of the second substrate 24 to the first surface 211 of the first substrate 21.

Finally, a second molding compound 26 is provided. The second molding compound 26 encapsulates the first surface 211 of the first substrate 21, the first molding compound 23, a portion of the second substrate 24, and the first wires 25, and the second pads 244 on the first surface 241 of the second substrate 24 are exposed outside the second molding compound 26, thus forming a mold area opening 29.

Preferably, the fourth embodiment of the stackable semiconductor package in FIG. 5 is described. The second surface 552 of the second substrate 54 further includes a second chip 55 and a third molding compound 56. The first surface 551 of the second chip 55 is adhered to the second surface 542 of the second substrate 54 by the use of an adhesive layer 61. The second surface 552 of the second chip 55 is electrically connected to the second surface 542 of the second substrate 54 via a plurality of third wires 62. However, it is reasonable that the second chip 55 can be a flip chip attached to the second surface 541 of the second substrate 54. The third molding compound 56 encapsulates the second chip 55, the third wires 62, and a portion of the second surface 542 of the second substrate 54, and is directly adhered to the first molding compound 53 by the use of an adhesive layer 63.

While several embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

What is claimed is:

1. A stackable semiconductor package, comprising:
a first substrate having a first surface and a second surface;
a chip disposed on the first surface of the first substrate, and electrically connected to the first surface of the first substrate;
a first molding compound encapsulating the chip and a portion of the first surface of the first substrate;
a second substrate disposed above the first molding compound, and having a first surface and a second surface, wherein the first surface of the second substrate has a plurality of first pads and a plurality of second pads disposed thereon, and the area of the first molding compound is adjusted according to the area of the second substrate, so as to support the second substrate;
a plurality of first wires electrically connecting the first pads of the second substrate to the first surface of the first substrate; and
a second molding compound encapsulating the first surface of the first substrate, the first molding compound, the first wires, and a portion of the second substrate, and exposing the second pads on the first surface of the second substrate.

2. The stackable semiconductor package as claimed in claim 1, further comprising a plurality of second wires for electrically connecting the chip and the first surface of the first substrate, wherein the chip is adhered to the first surface of the first substrate and the first molding compound encapsulates the second wires.

3. The stackable semiconductor package as claimed in claim 1, wherein the chip is a flip chip attached to the first surface of the first substrate.

4. The stackable semiconductor package as claimed in claim 1, wherein the second surface of the second substrate is directly adhered to the first molding compound via an adhesive layer.

5. The stackable semiconductor package as claimed in claim 1, further comprising a second chip and a third molding compound, wherein the second chip is disposed on the second surface of the second substrate and is electrically connected to the second surface of the second substrate, and the third molding compound encapsulates the second chip and a portion of the second surface of the second substrate and is directly adhered to the first molding compound via an adhesive layer.

6. The stackable semiconductor package as claimed in claim 5, further comprising a plurality of third wires for electrically connecting the second chip and the second surface of the second substrate, wherein the second chip is adhered to the second surface of the second substrate and the third molding compound encapsulates the third wires.

7. The stackable semiconductor package as claimed in claim 5, wherein the second chip is a flip chip attached to the second surface of the second substrate.

8. The stackable semiconductor package as claimed in claim 1, further comprising a semiconductor device disposed on the chip and electrically connected to the chip and encapsulated by the first molding compound.

9. The stackable semiconductor package as claimed in claim 8, wherein the semiconductor device is a chip.

10. The stackable semiconductor package as claimed in claim 8, wherein the semiconductor device is a package.

11. The stackable semiconductor package as claimed in claim 1, further comprising a semiconductor device disposed on the first surface of the second substrate and electrically connected to the first surface of the second substrate and encapsulated by the second molding compound.

12. The stackable semiconductor package as claimed in claim 11, wherein the semiconductor device is a chip.

13. The stackable semiconductor package as claimed in claim 11, wherein the semiconductor device is a package.

14. The stackable semiconductor package as claimed in claim 1, wherein the first pads are disposed on the periphery of a corresponding position of the chip.
